(19) United States
(12) Patent Application Publication
(10) Pub. No.: US 2011/0198514 A1
(43) Pub. Date: Aug. 18, 2011

(54) USE OF PATTERN RECOGNITION TO ALIGN PATTERNS IN A DOWNSTREAM PROCESS

(75) Inventors: Paul J. Murphy, Reading, MA (US); Nicholas P.T. BATEMAN, Reading, MA (US)

(73) Assignee: VARIAN SEMICONDUCTOR EQUIPMENT ASSOCIATES, INC., Gloucester, MA (US)

(21) Appl. No.: 13/073,437

(22) Filed: Mar. 28, 2011

Related U.S. Application Data
(63) Continuation of application No. 12/487,046, filed on Jun. 18, 2009.
(60) Provisional application No. 61/074,231, filed on Jun. 20, 2008.

(51) Int. Cl. H01J 37/08

(52) U.S. Cl. 250/492.21

(57) ABSTRACT

An improved, lower cost method of processing substrates, such as to create solar cells is disclosed. The doped regions are created on the substrate, using a mask or without the use of lithography or masks. After the implantation is complete, visual recognition is used to determine the exact region that was implanted. This information can then be used by subsequent process steps to maintain this alignment. This information can also be fed back to the ion implantation equipment to modify the implant parameters. These techniques can also be used in other ion implanter applications.

This application is a continuation of U.S. application Ser. No. 12/487,046, filed Jun. 18, 2009, which claims priority to U.S. Provisional Application Ser. No. 61/074,231, filed Jun. 20, 2008, the disclosures of which are herein incorporated by reference in their entirety.

### BACKGROUND OF THE INVENTION

Solar cells are typically manufactured using the same processes used for other semiconductor devices, often using silicon as the substrate material. A semiconductor solar cell is a simple device having an in-built electric field that separates the charge carriers generated through the absorption of photons in the semiconductor material. This electric-field is typically created through the formation of a p-n junction (diode) which is created by differential doping of the semiconductor material. Doping a part of the semiconductor substrate (e.g. surface region) with impurities of opposite polarity forms a p-n junction that may be used as a photovoltaic device converting light into electricity.

FIG. 1 shows a cross section of a representative substrate 100, comprising a solar cell. Photons 10 enter the solar cell 100 through the top surface 105, as signified by the arrows. These photons pass through an anti-reflective coating 110, designed to maximize the number of photons that penetrate the substrate 100 and minimize those that are reflected away from the substrate.

Internally, the substrate 100 is formed so as to have a p-n junction 120. This junction is shown as being substantially parallel to the top surface 105 of the substrate 100 although there are other implementations where the junction may not be parallel to the surface. The solar cell is fabricated such that the photons enter the substrate through the n-doped region, also known as the emitter 130. While this disclosure describes p-type bases and n-type emitters, n-type bases and p-type emitters can also be used to produce solar cells and are within the scope of the disclosure. The photons with sufficient energy (above the bandgap of the semiconductor) are able to promote an electron within the semiconductor material's valence band to the conduction band. Associated with this free electron is a corresponding positively charged hole in the valence band. In order to generate a photocurrent that can drive an external load, these electron hole (e-h) pairs need to be separated. This is done through the built-in electric field at the p-n junction. Thus any e-h pairs that are generated in the depletion region of the p-n junction get separated, as are any other minority carriers that diffuse to the depletion region of the device. Since a majority of the incident photons are absorbed in near surface regions of the device, the minority carriers generated in the emitter need to diffuse across the depth of the emitter to reach the depletion region and get swept across to the other side. Thus to maximize the collection of photo-generated current and minimize the chances of carrier recombination in the emitter, it is preferable to have the emitter region 130 be very shallow.

Some photons pass through the emitter region 130 and enter the base 140. These photons can then excite electrons within the base 140, which are free to move into the emitter region 130, while the associated holes remain in the base 140. As a result of the charge separation caused by the presence of this p-n junction, the extra carriers (electrons and holes) generated by the photons can then be used to drive an external load to complete the circuit.

By externally connecting the emitter region 130 to the base 140 through an external load, it is possible to conduct current and therefore provide power. To achieve this, contacts 150, typically metallic, are placed on the outer surface of the emitter region 130 and the base 140. Since the base 140 does not receive the photons directly, typically its contact 150b is placed along the entire outer surface. In contrast, the outer surface of the emitter region 130 receives photons and therefore cannot be completely covered with contacts. However, if the electrons have to travel great distances to the contact, the series resistance of the cell increases, which lowers the power output. In an attempt to balance these two considerations; the distance that the free electrons must travel to the contact, and the amount of exposed emitter surface 160; most applications use contacts 150a that are in the form of fingers. FIG. 2 shows a top view of the solar cell of FIG. 1. The contacts are typically formed so as to be relatively thin, while extending the width of the solar cell. In this way, free electrons need not travel great distances, but much of the outer surface of the emitter is exposed to the photons. Typical contact fingers 150a on the front side of the wafer are 0.1 mm with an accuracy of +/−0.1 mm. These fingers 150a are typically spaced between 1-5 mm apart from one another. While these dimensions are typical, other dimensions are possible and contemplated herein.

A further enhancement to solar cells is the addition of heavily doped substrate contact regions. FIG. 3 shows a cross section of this enhanced solar cell. The cell is as described above in connection with FIG. 1, but includes heavily n-doped contact regions 170. These heavily doped contact regions 170 correspond to the areas where the metallic fingers 150a will be affixed to the substrate 100. The introduction of these heavily doped contact regions 170 allows much better contact between the substrate 100 and the metallic fingers 150a and significantly lowers the series resistance of the cell. This pattern of including heavily doped regions on the surface of the substrate is commonly referred to as selective emitter design. These heavily doped regions may be created by implanting ions in these regions. Thus, the terms “implanted region” and “doped region” may be used interchangeably throughout this disclosure.

A selective emitter design for a solar cell also has the advantage of higher efficiency cells due to reduced minority carrier losses through recombination due to lower dopant/impurity dose in the exposed regions of the emitter layer. The higher doping under the contact regions provides a field that collects the majority carriers generated in the emitter and repels the excess minority carriers back toward the p-n junction.

Such structures are typically made using traditional lithography (or hard masks) and thermal diffusion. An alternative is to use implantation in conjunction with a traditional lithographic mask, which can then be removed easily before dopant activation. Yet another alternative is to use a shadow mask or stencil mask in the implanter to define the highly doped areas for the contacts. All of these techniques utilize a fixed masking layer (either directly on the substrate or in the beamline).

All of these alternatives have significant drawbacks. For example, the processes enumerated above all contain multiple process steps. This causes the cost of the manufacturing process to be prohibitive and may increase wafer breakage rates. These options also suffer from the limitations associated with the special handling of solar wafers, such as aligning the mask with the substrate and the cross contamination with materials that are dispersed from the mask during ion implantation.

Consequently, efforts have been made to reduce the cost and effort required to dope a pattern onto a substrate. While some of these efforts may be successful in reducing cost and processing time, often these modifications come at the price of reduced accuracy. Typically, in semiconductor processes, masks are very accurately aligned. Subsequent process steps rely on this accuracy. For example, referring to FIG. 4, after the heavily doped regions 170 have been implanted, metallic fingers 150a are pasted to the substrate. Each of these processes is usually performed relative to some reference mark or fiducial. This mark may be an edge or corner of the substrate, or a specific mark or feature on the substrate. Since each of these process steps is typically referenced to a specific point, it is imperative that a high degree of accuracy be maintained. These efforts to reduce cost and processing steps degrade this accuracy, thereby potentially impacting the performance and yields of the devices made using these methods.

Therefore, these exists a need to produce solar cells where the number and complexity of the process steps is reduced, while maintaining adequate accuracy so that subsequent process steps are correctly positioned. While applicable to solar cells, the techniques described herein are applicable to other doping applications.

### SUMMARY OF THE INVENTION

An improved, lower cost method of processing substrates, such as to create solar cells is disclosed. The doped regions are created on the substrate, using a mask or without the use of lithography or masks. After the implantation is complete, visual recognition is used to determine the exact region that was implanted. This information can then be used by subsequent process steps to maintain this alignment. This information can also be fed back to the ion implantation equipment to modify the implant parameters. These techniques can also be used in other ion implanter applications.

### BRIEF DESCRIPTION OF THE FIGURES

FIG. 1 shows a cross section of a solar cell of the prior art;

FIG. 2 shows a top view of the solar cell of FIG. 1;

FIG. 3 shows a cross section of a solar cell using selective emitter design;

FIG. 4a shows a top view of the solar cell of FIG. 3;

FIG. 4b shows a top view of the solar cell of FIG. 4a with misaligned implanted regions;

FIG. 4c shows a top view of the solar cell of FIG. 4a with misaligned implanted regions and repositioned contacts, based on the actual position of the implanted regions;

FIG. 5 shows a representative coordinate system;

FIG. 6 is a representative illustration of an ion implanter used in accordance with an embodiment;

FIG. 7 is an embodiment showing implantation of a substrate to form the doped regions shown in FIG. 4;

FIG. 8 is an embodiment of a substrate having implanted regions and a fiducial;

FIG. 9 is an embodiment of a substrate having implanted regions caused by a misaligned implant;

FIG. 10 is a first embodiment of process control for a substrate having implanted regions;

FIG. 11 is a second embodiment of process control for a substrate having implanted regions;

FIG. 12 is a third embodiment of process control for a substrate having implanted regions; and

FIG. 13 is a substrate that has been implanted.

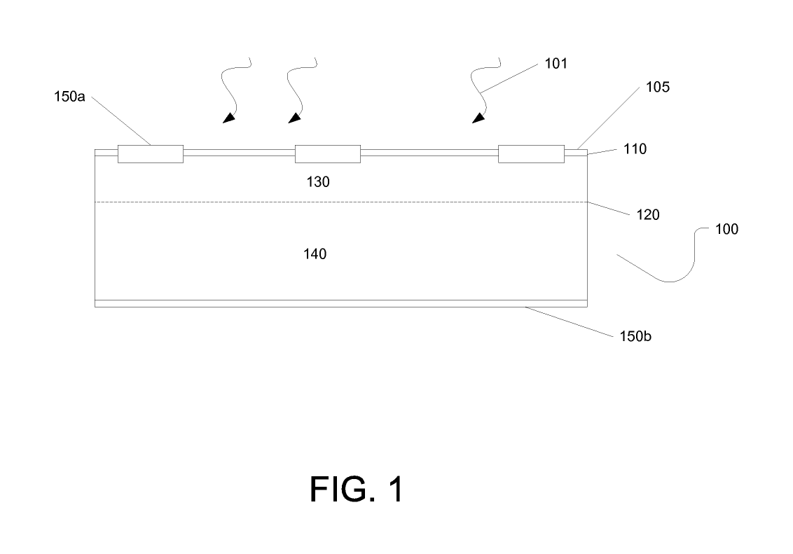

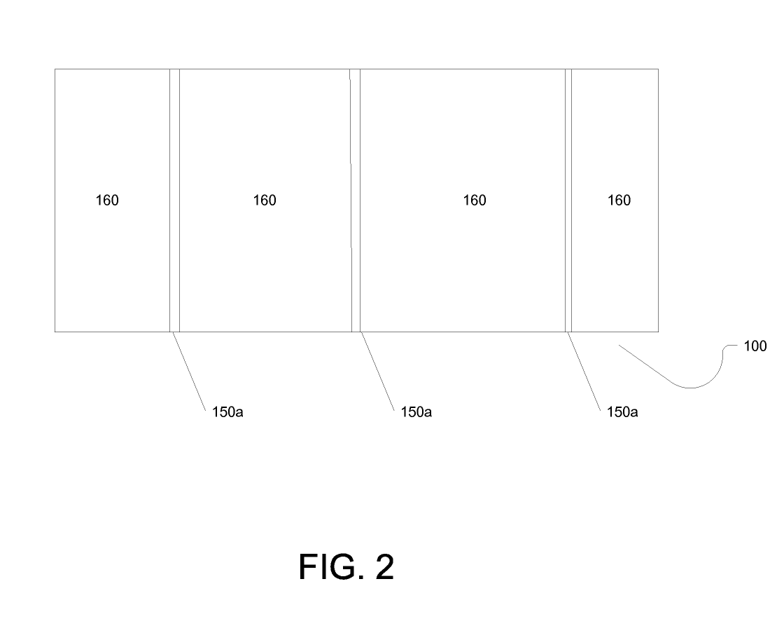

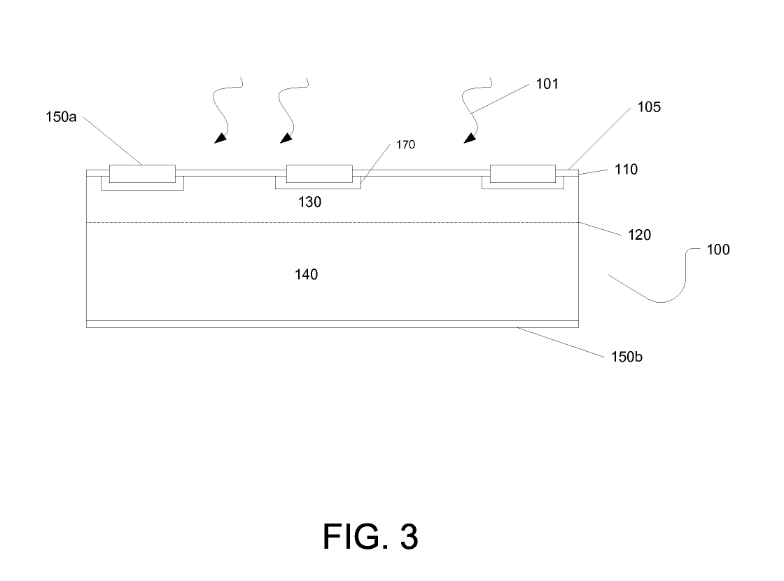

### DETAILED DESCRIPTION OF THE INVENTION

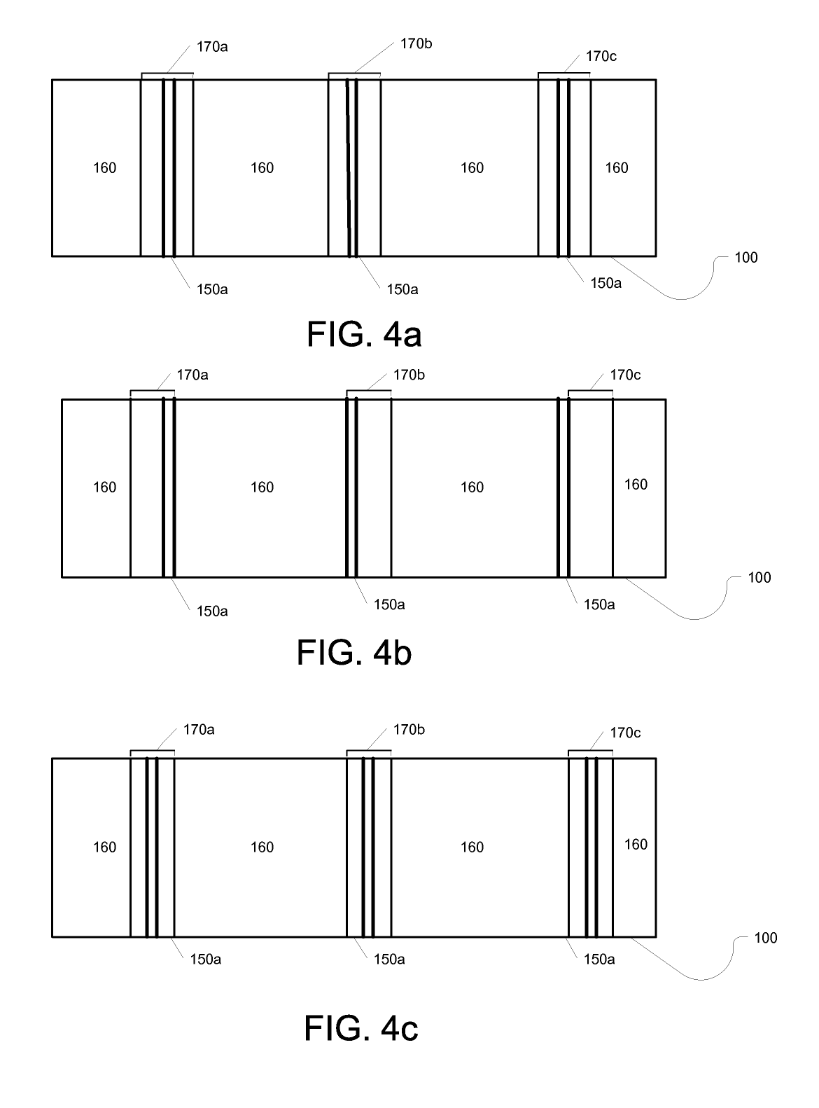

FIG. 4a shows a top view of the solar cell manufactured using the methods of the present disclosure. The solar cell is formed on a semiconductor substrate 100. The substrate can be any convenient size, including but not limited to circular, rectangular, or square. Although not a requirement, it is preferable that the width of the substrate 100 be less than the width of the ion beam used to implant ions in the substrate 100. However, no such limitation exists with respect to the orthogonal direction of the substrate. In other words, a substrate 100 can be arbitrarily long, and can be in the shape of a roll of solar cell material. Typically, the substrates for solar cells are very thin, often on the order of 300 microns thick or less.

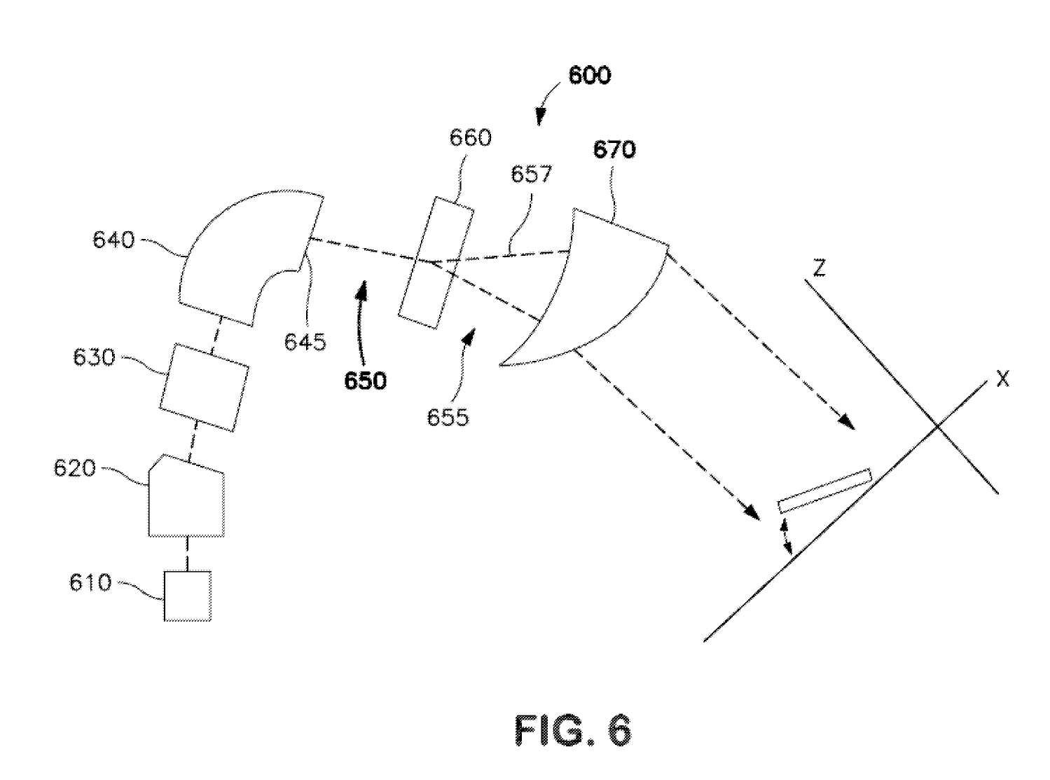

As described above, the solar cell has an n-doped emitter region and a p-doped base. The substrate is typically p-doped and forms the base, while ion implantation is used to create the emitter region. A block diagram of a representative ion implanter 600 is shown in FIG. 6. An ion source 610 generates ions of a desired species, such as phosphorus or boron. A set of electrodes (not shown) is typically used to attract the ions from the ion source. By using an electrical potential of opposite polarity to the ions of interest, the electrodes draw the ions from the ion source, and the ions accelerate through the electrode. These attracted ions are then formed into a beam, which then passes through a source filter 620. The source filter is preferably located near the ion source. The ions within the beam are accelerated/decelerated in column 630 to the desired energy level. A mass analyzer magnet 640, having an aperture 645, is used to remove unwanted components from the ion beam, resulting in an ion beam 650 having the desired energy and mass characteristics passing through resolving aperture 645.

In certain embodiments, the ion beam 650 is a spot beam. In this scenario, the ion beam passes through a scanner 660, preferably an electrostatic scanner, which deflects the ion beam 650 to produce a scanned beam 655 wherein the individual beamlets 657 have trajectories which diverge from scan source 665. In certain embodiments, the scanner 660 comprises separated scan plates in communication with a scan generator. The scan generator creates a scan voltage waveform, such as a sine, sawtooth or triangle waveform having amplitude and frequency components, which is applied to the scan plates. In a preferred embodiment, the scanning waveform is typically very close to being a triangle wave (constant slope), so as to uniformly expose the scanned beam at every position of the substrate for nearly the same amount of time. Deviations from the triangle are used to make the beam uniform. The resultant electric field causes the ion beam to diverge as shown in FIG. 6.

An angle corrector 670 is adapted to deflect the divergent ion beamlets 657 into a set of beamlets having substantially parallel trajectories. Preferably, the angle corrector 670 comprises a magnet coil and magnetic pole pieces that are spaced apart to form a gap, through which the ion beamlets pass. The coil is energized so as to create a magnetic field within the gap, which deflects the ion beamlets in accordance with the strength and direction of the applied magnetic field. The magnetic field is adjusted by varying the current through the magnet coil.

Alternatively, other structures, such as parallelizing lenses, can also be utilized to perform this function.

Following the angle corrector 670, the scanned beam is targeted toward the substrate, such as the solar cell to be processed. The scanned beam typically has a height (Y dimension) that is much smaller than its width (X dimension). This height is much smaller than the substrate, thus at any particular time, only a portion of the substrate is exposed to the ion beam. To expose the entire substrate to the ion beam, the substrate must be moved relative to the beam location.

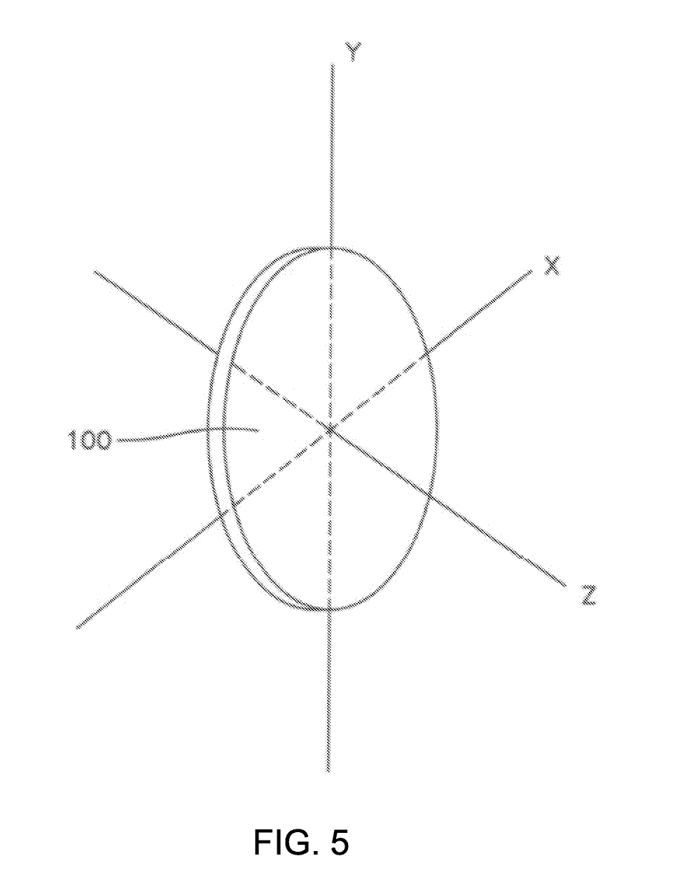

The substrate, such as a solar cell, is attached to a substrate holder. The substrate holder provides a plurality of degrees of movement. For example, the substrate holder can be moved in the direction orthogonal to the scanned beam. A sample coordinate system in shown in FIG. 5. Assume the beam is in the XZ plane. This beam can be a ribbon beam, or a scanned spot beam. The substrate holder can move in the Y direction. By doing so, the entire surface of the substrate 100 can be exposed to the ion beam, assuming that the substrate 100 has a smaller width than the ion beam (in the X dimension).

In addition to beam line ion implanters, plasma doping systems can also be used. A plasma doping system forms a plasma containing the dopant using an electron cyclotron resonance plasma source, a helicon plasma source, a capacitively coupled plasma source, an inductively coupled plasma source, a DC glow discharge, a microwave source, or an RF source, as examples. The substrate, which is located within a chamber containing this plasma, is then biased using either a pulse or DC voltage and ions are accelerated into the surface of the substrate. Other ion implanters, including those with mass analysis, may be used.

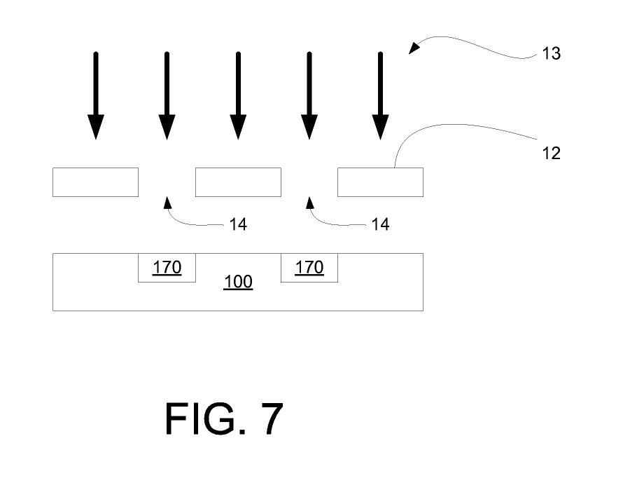

There are a number of methods that can be used to create the doping pattern shown in FIG. 4a. In some embodiments, the doped region 170 is created by traditional implantation techniques. For example, an ion beam can be used to implant the surface of the substrate 100 which is exposed to the beam. FIG. 7 shows a mask 12 disposed between the source of ions and the substrate 100. The mask 12 includes one or more apertures 14 that allow the passage of ions 13. The mask 12 will block ions 13 that do not pass through the apertures 14. Those areas which are exposed to the ion beam become implanted or doped regions 170. If a sufficient amount of ions are implanted, the region 170 may become amorphized. Those areas which do not receive ions remain undoped, or lightly doped regions 160.

The implanted regions 170 are formed on the substrate 100 and correspond to the location of the mask 12 as illustrated in FIG. 7. In some embodiments, the implanted regions 170 are visible on the surface of the substrate 100. The dose of the ions 13 may be configured in some embodiments to form a visible pattern of implanted regions 170 using the mask 12. In other embodiments, the dose may be sufficient to amorphize the region.

In other embodiments, the pattern shown in FIG. 4a may be created without a mask. In one embodiment, the movement of the substrate holder is modified so as to create longer dwell times at the regions to be implanted. In other words, the substrate holder is moved more quickly in the Y direction over those portions of the substrate that are not to be implanted (i.e. the undoped regions 160). Once the ion beam is positioned over a region that is to be doped (i.e. the implanted region (170), the speed of the substrate holder in the Y direction slows. This slower speed is maintained while the ion beam is over this region. Once that region has been fully exposed, the translational speed of the substrate holder increases so as to quickly pass over the other regions 160. This process is repeated until the entire substrate has been implanted.

In the case of a spot beam, a similar technique can be used to move the substrate holder at a variable speed in the Y direction, based on the position on the substrate. If the substrate holder also moves in the X direction to scan across the wafer, the holder can vary the speed in the X direction to achieve the same results described above. In other words, the substrate holder moves quickly in the X direction while exposing region 160 of the substrate, but slows when exposing the implanted region 170. Alternatively, the speeds of the substrate holder can be varied in both the X and Y directions if desired.

Alternatively, the scanner 660 can be controlled to create a similar result. Assume, in a scanned spot beam implementation, for example, that the substrate holder moves in the Y direction, and that the scanner 660 causes the spot beam to move in the X direction. By varying the frequency of the sawtooth wave used to control the scanner, the rate that the spot beam traverses the substrate can be modified. In one scenario, the frequency of the scanner control signal is increased as the ion beam passes over the undoped region 160, and is slowed when the ion is exposed to the implanted region 170. In this way, the dwell time of the undoped region 160 is less than that of the implanted region 170. In another scenario, the waveform of the scanner control signal is modified so that the spot beam is positioned so as not to strike the substrate when passing through the undoped region 160, and only scans when in the implanted region 170. Combining the modification to the scanner input waveform with an alteration to the speed of the substrate holder in the Y direction can also be performed.

Other methods of varying the ion dose, scan rate, beam current or beam energy may also be used to form these implanted regions 170, without the use of a mask. The particular technique used to implant ions is not limited; all such techniques are within the scope of the disclosure.

To create the desired implantation patterns, it is important for the system to understand the position of the substrate relative to the ion beam. In other words, the system must be aware which region is being exposed in order to supply the proper amount of ions. This information can be determined in a number of ways.

First, the system can rely strictly on timing. In other words, the synchronization of the substrate holder to the other components of the system is accomplished based on the time elapsed since the start of the operation. This timing produces an implant pattern that is then assumed to be correct for all subsequent process steps. For example, if the speed profile of the substrate holder is known, the regions that are being implanted can be calculated. Of course, if there is any error in initial position, speed, or other parameters, these calculations will be necessarily incorrect.

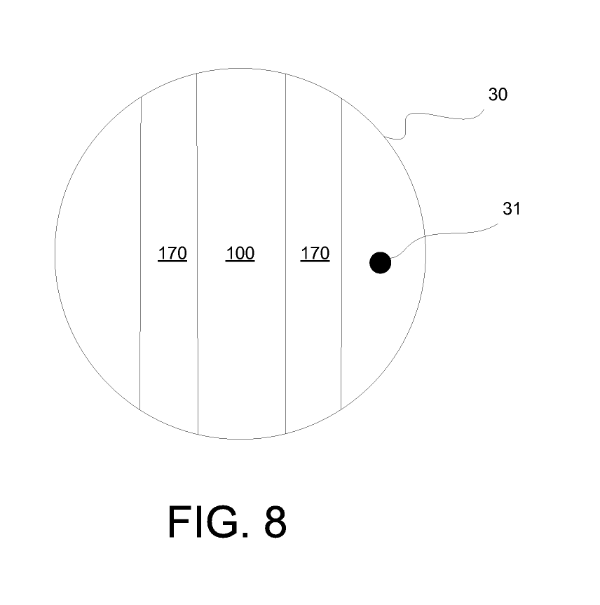

A more accurate approach is to include reference marks, or fiducials, such as along the edge of the substrate. The system can determine the position of the substrate with respect to the ion beam based on these marks, and operate accordingly. This method is preferably in that the system does not need any information concerning the implant pattern prior to starting the operation. The patterns on the substrate supply the necessary information for the system to correctly implant the substrate. Such patterns and marking systems are well known to those skilled in the art. FIG. 8 is an embodiment of a substrate having an implanted region and a fiducial. As described above, this fiducial, or reference point, may be a specific mark or feature of the substrate 100.

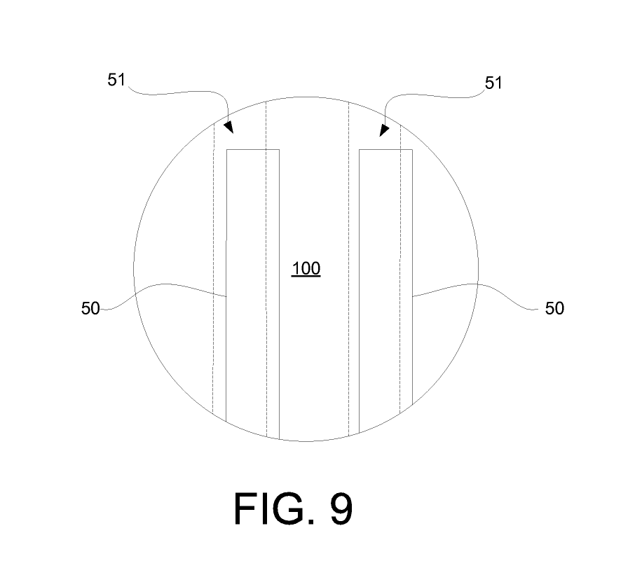

FIG. 9 is an embodiment of a substrate having misaligned implanted regions. This may have occurred due to a misaligned mask, or an error that occurred in one of the maskless techniques described above. The misalignment also may be caused by an incorrect implant or incorrect implant parameters in some embodiments. The substrate 100 has implanted regions 50 caused by a misaligned mask. These implanted regions are different than the desired implanted regions 51 that are outlined by a dashed line in FIG. 9. This misalignment seen in the embodiment of FIG. 9 can be measured.

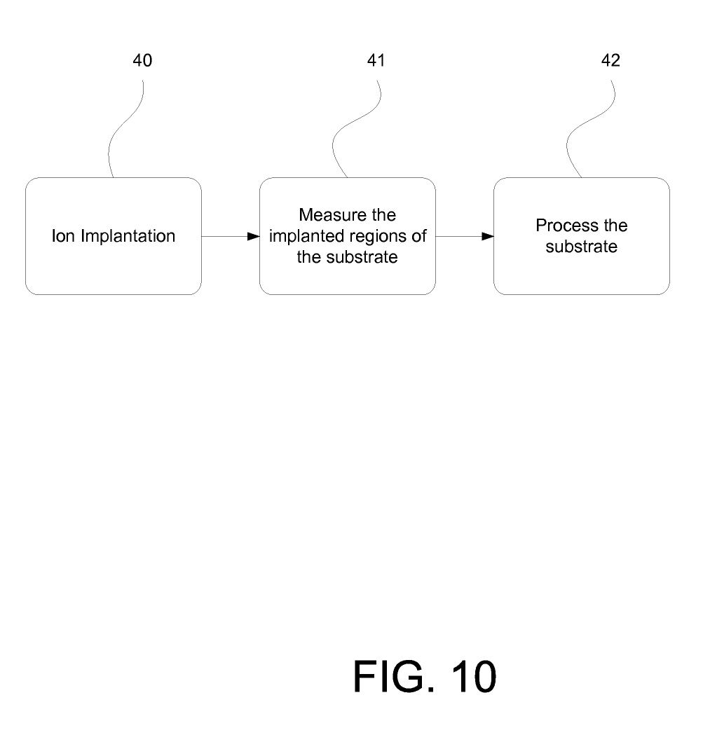

FIG. 10 is a first embodiment of process control for a substrate having implanted regions. An implant 40 will dope regions of a substrate. A sufficient amount of ions may cause the region to amorphize. Then the process will measure 41 the implanted regions of the substrate or the pattern of the implanted regions. In one particular embodiment, the process measures the pattern of the implanted regions with respect to a fiducial, such as, for example, an edge of a substrate. Visual detection may be used in some embodiments for the measurement 41. A linear charge-coupled device (CCD) array, a 2D CCD array, laser based surface metrologies, ellipsometry, photoluminescence, reflectance from a scanned laser, a scanned photodiode with a lens to focus light from the wafer, or simple photo may all be used for measurement 41. Such measurement techniques could also extend into the ultraviolet part of the electromagnetic spectrum.

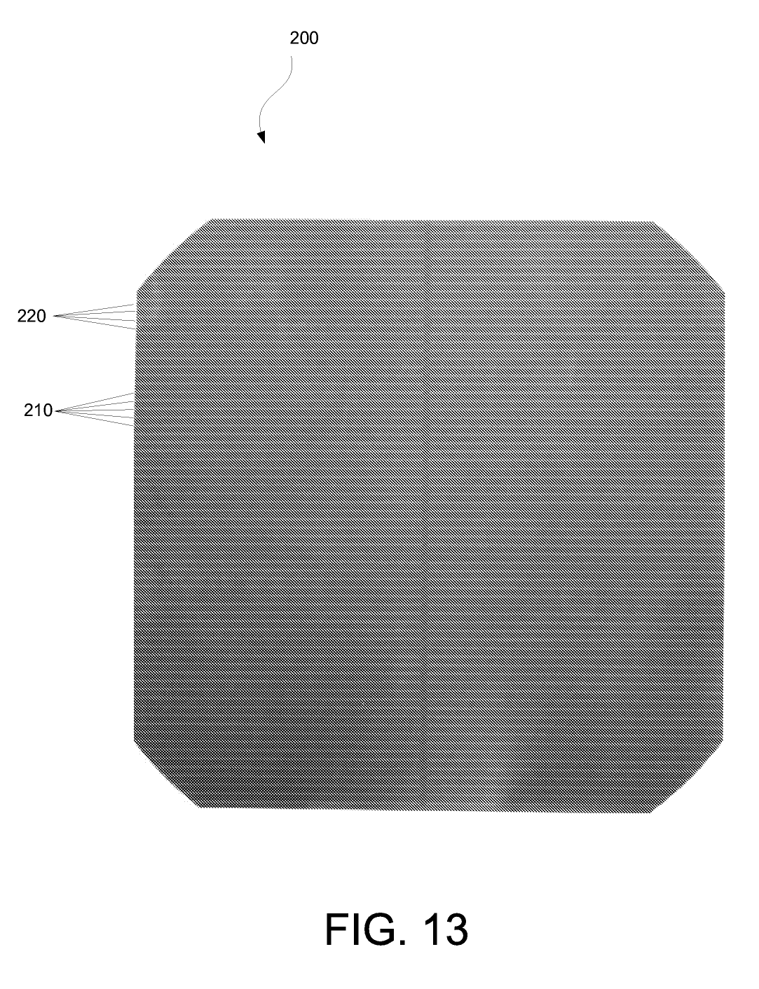

FIG. 13 shows a substrate 200 that has been implanted. In this embodiment, the substrate 200 has been implanted using a striped pattern. The light colored stripes 210 are those portions of the substrate 200 that have been implanted. Note that these areas are visually detectable. The darker areas 220 are those portions of the substrate 200 that have not been implanted. Any number of detection systems can be used to determine the locations of the implanted portions.

A CCD array will measure the intensity of the reflected signal by looking directly at the substrate, by looking for reflectance, or by looking at an angle and measuring a lack of signal. The implanted regions of the substrate will respond approximately the same as the angle is adjusted. In other words, as the angle of the wafer to the probing light is changed, the amorphized region will change slowly, while the crystalline unimplanted region will have a spike in the reflection at a specific angle. The measurement 41 may measure from a fiducial, such as a mark or the edge of the substrate, and measure to the point where the change in reflectance begins or is over a threshold value. In another embodiment, measurement 41 includes a CCD array that measures the entire area of a changed reflectance in a substrate and calculates to the mean or another fit shape from the data.

Transmission in the infrared spectrum may also be used for the measurement 41. Implanted areas of a substrate will absorb the IR energy better than non-implanted areas of a substrate. The signal when using IR may be processed similar to that of a CCD array.

Other measurement techniques, such as crystallographic measurements can also be used. For example, electron or x-ray scattering can also be used to perform the required measurement.

The measurement 41 may measure more than one line with respect to the fiducial. Using a known mask geometry, a transfer fit function between the image points and the mask may be calculated. In one embodiment, many points across the substrate are measured. Accounting for beam spread, distortion, lateral and angular error in mask position, an algorithm CaO be used to determine the best fit with respect to the fiducial.

The measurement 41 may be linked to an equipment control system for supplier quality assurance (SQA) and feed forward error data handling. The measurement 41 may compare information to a control limit in some embodiments. For example, tolerances may be established such that, if the actual implanted region deviates too far from the desired region, the substrate may be discarded or marked for removal.

In another embodiment, mask alignment errors may be minimized in later processing steps. The substrate may be processed 42 after the measurement 41. This processing 42 may include one or more ion implantation steps and/or metallization steps. In one particular embodiment, the measurement 41 will determine the actual position of the mask as used in the implant 40. Error correction may be included as the substrate is processed 42. The measurement 41 may transmit information to a factory management tool instead of directly to individual tools or an equipment control system.

These process steps 42 may anticipate or compensate for mask misalignment during the implant 40. In one particular embodiment, later processing steps 42 compensate for mask misalignment or implant misalignment during the implant 40 by adjusting the regions of the substrate upon which work or process steps will be performed. Later processing steps 42 may compensate for each substrate individually.

One example of processing 42 is screen printing or inkjet printing of a paste containing an aluminum and/or silver alloy for contacting during the fabrication of solar cells. This processing 42 may have its alignment adjusted to compensate for misalignment of the mask or implant. In one particular embodiment, the measurement 41 measures the implanted pattern relative to the edge of the substrate. If the implanted pattern is, for example, 1 mm away from nominal, the screen printer or inkjet printer alignment is adjusted so the lines will be laid down 1 mm from nominal. This particular embodiment may use a servomotor that feeds the substrate into the screen printer and compensates for the misalignment of the implanted region.

For example, FIG. 4a shows a substrate with a simple pattern, wherein there are three vertical implanted regions. The factory tools may be configured to process the substrate, assuming that the three implants start and end at specific distances from a fiducial, which in this case is the leftmost edge of the substrate. Assume that the first implanted region 170a was designed to begin 20 mm from the leftmost edge of the substrate, and stop 23 mm from that edge. Similarly, the second implanted region 170b starts 40 mm from the leftmost edge and stops 43 mm from that edge. Finally, the third implanted region 170c begins 60 mm from the leftmost edge and ends 63 mm from that edge. A subsequent process is intended to screen print or inkjet print in the middle of these implanted areas. For example the paste is to be 1 mm in width and centered in the implanted regions 170. Thus, the paste should be applied at 21, 41 and 61 mm from the leftmost edge, respectively.

However, after the substrate is implanted, the measuring process 41 determined that the three implanted areas are actually as follows:
170a is between 19 and 22 mm from the leftmost edge,
170b is between 41 and 44 mm from the leftmost edge, and
170c is between 62 and 65 mm from the leftmost edge.

Without correction to the subsequent screen printing or inkjet printing step, the leftmost contact will be deposited at the right edge of the implanted region 170a. The middle contact will be deposited at the left edge of implanted region 170b and the rightmost contact will be deposited outside of implanted region 170c. FIG. 4b shows the substrate of FIG. 4a with these misaligned regions.

However, the measuring step 41 determines these new coordinates, based on visual inspection of the substrate, and relays this information to the rest of the equipment. Based on this feedforward system, the screen printing or inkjet printing step will adjust the placement of the contacts 150a to be located at 20, 42 and 63 mm, respectively. The resulting substrate, with the contacts placed based on the actual locations of the implanted regions 170, is shown in FIG. 4c.

Other example of processing 42 may be masking, a laser system, thermal etching, screen printing, inkjet printing or other printing steps. As described above, the calculated error is examined for the substrate. Downstream processes are aligned to the actual implanted region of the substrate. This alignment information may come from the implanter, a separate measurement tool, or through a factory interface. This alignment prevents the system from working on the incorrect parts of the substrate and reduces waste and production costs.

There are a number of ways that the results of the measuring step 41 can be used. In one embodiment, each substrate is identified, such as with an ID number. After the substrate has been implanted 40, it is measured 41. The resulting data is then stored in a database, associated with the substrate identification. In this way, subsequent process steps can query the database to determine the appropriate measurements and setting to be used with a particular substrate.

In another embodiment, each processing step is equipped with a dedicated measurement device, such as those described above. As the substrate enters the particular processing step, it is measured by the device. These measurements are then used to adjust the orientation and location of the steps that are to be applied to the substrate. In the example above, the CCD camera may be located with the screen printing equipment so as to measure the implanted regions just prior to the printing process. The measurements determined by the camera are then only used for a single process step.

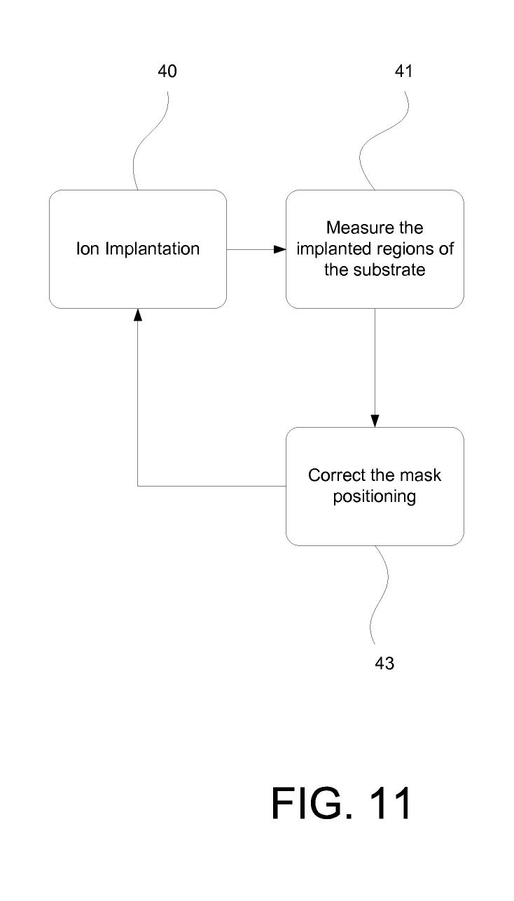

In an alternative embodiment, shown in FIG. 11, the measurement 41 may be used to correct the mask positioning 43 for subsequent processes. It also may be used to correct implant parameters in some embodiments. Continual correction of mask alignment or implant parameters may assist in the elimination of a lithography step. As an illustration, in the above example, the measured values of the implant regions 170 may be fed back to the ion implantation process. This information can then be used to adjust parameters of the implantation. In the case of a maskless implant, parameters, such as substrate holder speed profile, scan rate, or others may be tuned in response to this feedback. By providing continuous feedback to the maskless ion implantation station, it may be possible to increase the accuracy of such an implantation, such that a maskless implant achieves a greater degree of accuracy that currently possible. Such an improvement may enable subsequent stations to use predetermined parameters, which are not changed as a result of the measuring step 41.

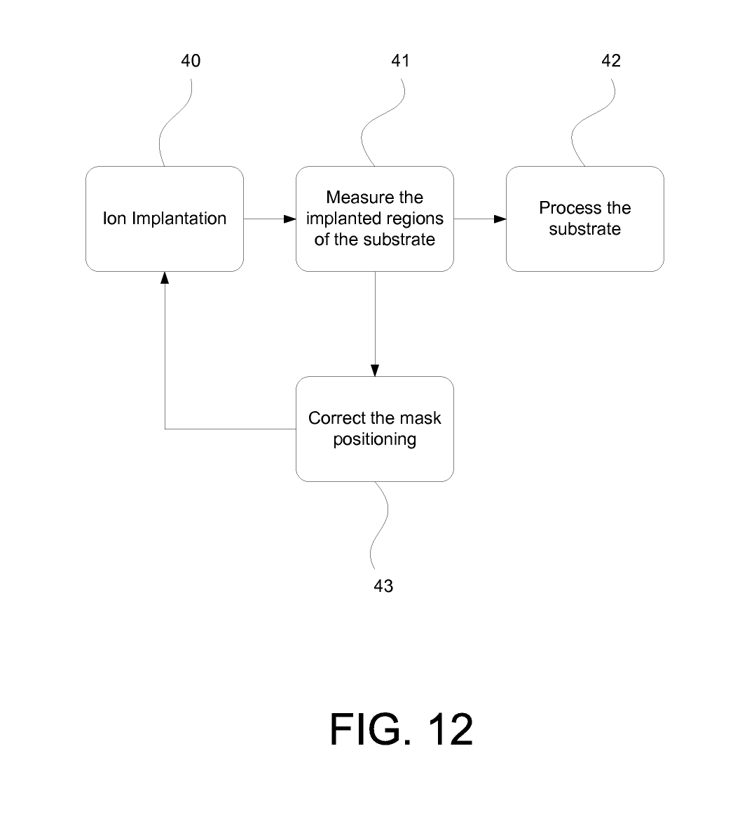

In another embodiment, shown in FIG. 12, the resulting of the measuring step 41 are used to both feedback information to the implantation step 40 and the feed forward data to the subsequent processing steps 42.

In one particular embodiment, the data gained from the measurement 41 may be combined with other measurement data obtained during substrate processing 42. This data may be used to perform statistical process control (SPC) on the implant and pattern alignment. Information, such as error margins and potential misalignments, may allow troubleshooting or may improve overall production of substrates by optimizing yield, throughput, or performance. Statistical data, such as means, may be used to make overall adjustments to the production process. In another particular embodiment, the control system or SPC may create a map of system pattern alignment. This map may allow for manual or automatic mask alignment or other process steps with respect to one another. SPC may also be used as an interlock on the implanter for the implant 40, meaning that the implanter may start or stop the implant 40 step.

One example of this process control method is for use in fabricating solar cells or photovoltaic devices. Another example of this process control method is in the production of integrated circuit substrates. Other substrates also may benefit from this process control method.

The terms and expressions which have been employed herein are used as terms of description and not of limitation, and there is no intention in the use of such terms and expressions of excluding any equivalents of the features shown and described (or portions thereof). It is also recognized that various modifications are possible within the scope of the claims. Other modifications, variations, and alternatives are also possible. Accordingly, the foregoing description is by way of example only and is not intended as limiting.

What is claimed is:

1. A method of processing a substrate, comprising:
implanting ions into an implanted portion of said substrate;
using a detection system to determine an actual location of said implanted portion; and
screen printing said substrate using said actual location, wherein a paste is applied to said implanted portion based on said actual location.

2. The method of claim 1, wherein said implanting is performed with the use of a mask.

3. The method of claim 1, wherein said detection system is selected from the group consisting of a CCD camera, an infrared camera, a photodiode, and a laser.

4. The method of claim 1, wherein said actual location is referenced to a fiducial.

5. The method of claim 1, wherein said substrate comprises an identifier and said actual location is stored in a database with said identifier.

6. The method of claim 5, wherein a subsequent process step accesses said database to determine said actual location.

7. The method of claim 1, wherein said implanting causes amorphization of said implanted portion.

8. The method of claim 7, wherein said amorphization causes visual differences in said substrate and said detection system determines said actual location based on said visual differences.

9. The method of claim 1, further comprising processing said substrate to produce a solar cell.

10. A method of processing a substrate, comprising:
implanting ions into a plurality of stripes on said substrate;
using a detection system to determine an actual location of said plurality of stripes; and
screen printing said substrate using said actual location, wherein a paste is applied to said plurality of stripes based on said actual location.

11. The method of claim 10, wherein said implanting is performed with the use of a mask.

12. The method of claim 10, wherein said detection system is selected from the group consisting of a CCD camera, an infrared camera, a photodiode, and a laser.

13. The method of claim 10, wherein said actual location is referenced to a fiducial.

14. The method of claim 10, wherein said substrate comprises an identifier and said actual location is stored in a database with said identifier.

15. The method of claim 14, wherein a subsequent process step accesses said database to determine said actual location.

16. The method of claim 10, wherein said implanting causes amorphization of said plurality of stripes.

17. The method of claim 16, wherein said amorphization causes visual differences in said substrate and said detection system determines said actual location based on said visual differences.

18. The method of claim 10, further comprising processing said substrate to produce a solar cell.
